(19) United States
(12) Patent Application Publication
(10) Pub. No.: US 2014/0226265 A1
(43) Pub. Date: Aug. 14, 2014

(54) ELECTRONIC APPARATUS

(71) Applicant: Kabushiki Kaisha Toshiba, Tokyo (JP)

(72) Inventor: Shigeyuki ITO, Tokorozawa-shi (JP)

(73) Assignee: Kabushiki Kaisha Toshiba, Tokyo (JP)

(21) Appl. No.: 13/975,951

(22) Filed: Aug. 26, 2013

Related U.S. Application Data
(63) Continuation of application No. PCT/JP2013/058627, filed on Mar. 25, 2013.

(30) Foreign Application Priority Data
Feb. 12, 2013 (JP) 2013-024887

(51) Int. Cl. H05K 7/02

(52) U.S. Cl. CPC H05K 7/02
USPC 361/679.01

(57) ABSTRACT

According to one embodiment, an electronic apparatus includes a display panel, a back cover which covers a rear side of the display panel, an outer edge region along an outer edge of the back cover, a first rib on an inner border of the outer edge region, a second rib along the first rib within the outer edge region, and a third rib continuous with the first rib and the second rib.

### CROSS-REFERENCE TO RELATED APPLICATIONS

This application is a Continuation Application of PCT Application No. PCT/JP2013/058627, filed Mar. 25, 2013 and based upon and claiming the benefit of priority from Japanese Patent Application No. 2013-024887, filed Feb. 12, 2013, the entire contents of all of which are incorporated herein by reference.

### FIELD

Embodiments described herein relate generally to an electronic apparatus comprising a display screen.

### BACKGROUND

In the market for electronic apparatuses, a model which is strong in impact, etc., and is highly reliable tends to be preferred. On the other hand, product price is becoming an important factor in determining market competitiveness. Thus, the balance between production costs and quality is becoming crucial.

### BRIEF DESCRIPTION OF THE DRAWINGS

A general architecture that implements the various features of the embodiments will now be described with reference to the drawings. The drawings and the associated descriptions are provided to illustrate the embodiments and not limit the scope of the invention.

FIG. 1 is an exemplary front elevation showing an image display device which is an example of an electronic apparatus of a first embodiment from a front direction.

FIG. 2 is an exemplary perspective illustration showing the image display device illustrated in FIG. 1 from a rear direction in a state that a unit cover is detached.

FIG. 3 is an exemplary perspective illustration in which a main body of the image display device illustrated in FIG. 2 is disassembled.

FIG. 4 is an exemplary perspective illustration showing a back cover of the image display device illustrated in FIG. 3 from a front direction (that is, showing an inner surface side of the back cover).

FIG. 5 is an exemplary perspective illustration showing an intermediate member of the image display device illustrated in FIG. 3 from a rear side.

FIG. 6 is an exemplary perspective illustration showing a vicinity of a first side (upper side) of the back cover illustrated in FIG. 4 in an enlarged scale.

FIG. 7 is an exemplary perspective illustration showing a vicinity of a corner of the back cover illustrated in FIG. 4 in an enlarged scale.

FIG. 8 is an exemplary cross-sectional view taken along a position of the F8-F8 line shown in FIG. 1.

FIG. 9 is an exemplary front view showing a back cover of an image display device which is an example of an electronic apparatus of a second embodiment from a front direction.

### DETAILED DESCRIPTION

Various embodiments will be described hereinafter with reference to the accompanying drawings. In general, according to one embodiment, an electronic apparatus includes: a display panel; a back cover which covers a rear side of the display panel; an outer edge region along an outer edge of the back cover; a first rib on an inner border of the outer edge region; a second rib along the first rib within the outer edge region; and a third rib continuous with the first rib and the second rib.

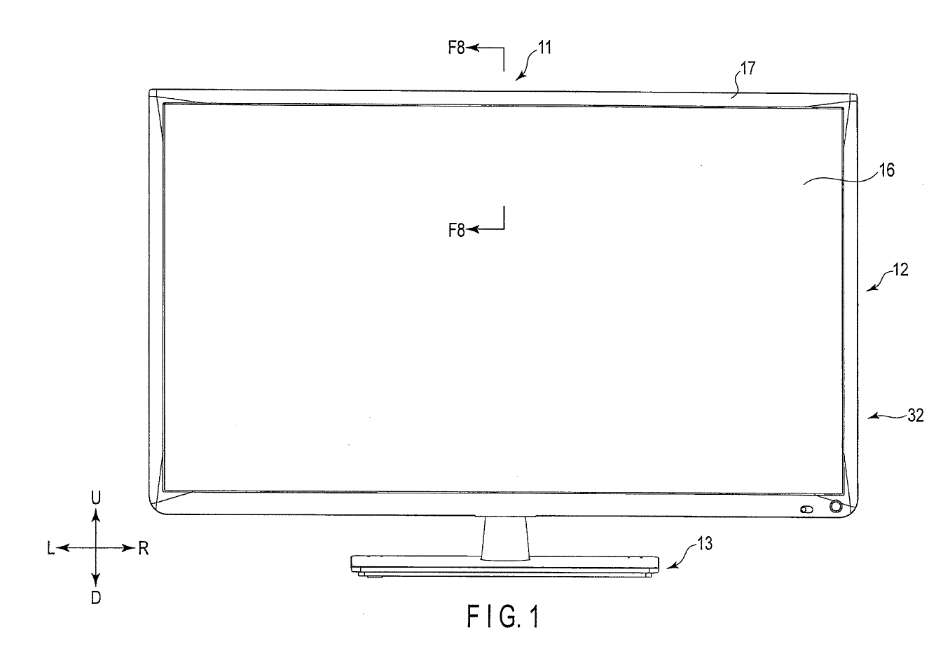

Hereinafter, a first embodiment of an image display device is explained with reference to FIG. 1 to FIG. 8. The image display device (television) of the embodiment is an example of an electronic apparatus, and comprises a substantially rectangular appearance. In the following embodiments, the near side (i.e., user side) is defined as a front direction F. The rear side from the perspective of a user is defined as a back direction B. The left side from the perspective of the user is defined as a left direction L. The right side from the perspective of the user is defined as a right direction R. The upper side from the perspective of the user is defined as an upward direction U. The lower side from the perspective of the user is defined as a downward direction D.

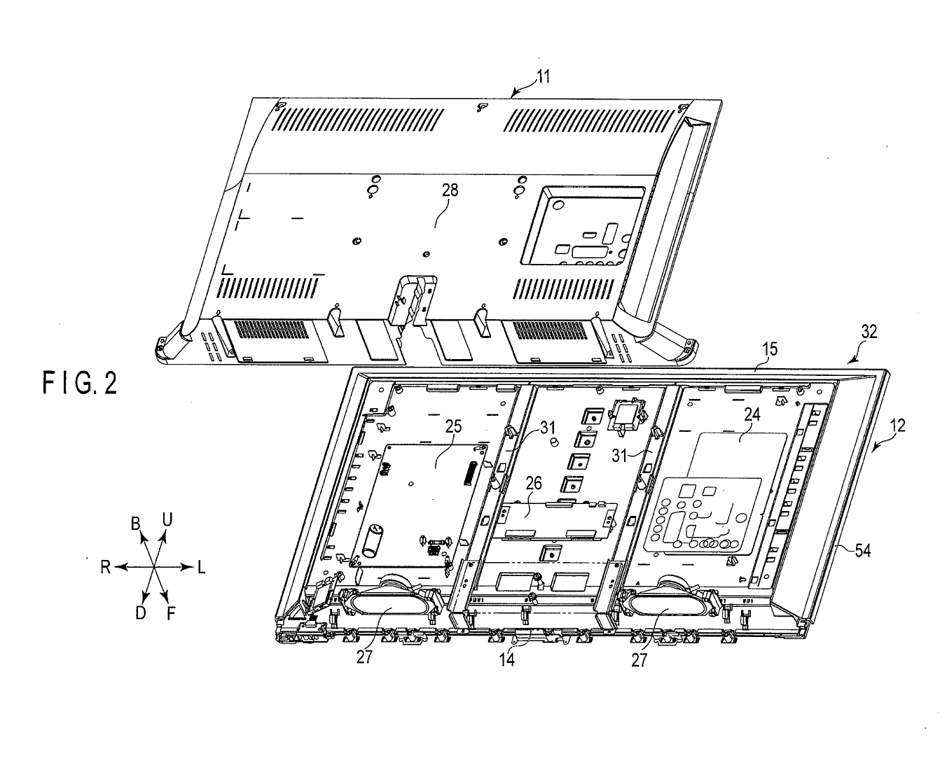

As shown in FIG. 1 and FIG. 2, the image display device 11 comprises a main body 12, and a leg 13 (a supporting portion, a stand) which supports the main body 12. The leg 13 is attached to a back cover 15 mentioned later via a reinforcing board 14 having a substantially L-shape in the cross section. Thus, the leg 13 is configured to support the main body 12 (refer to FIG. 2).

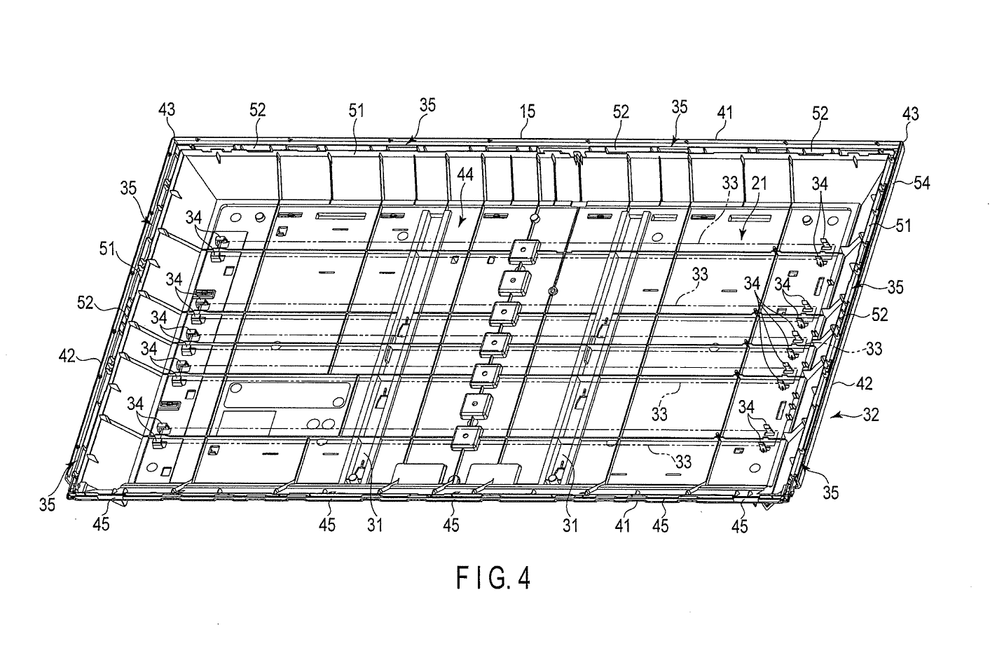

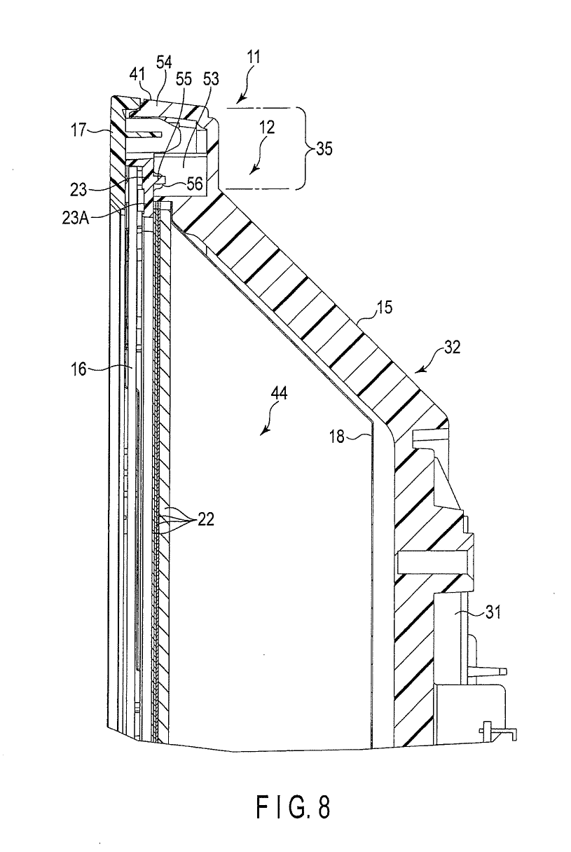

FIG. 1 to FIG. 3 indicate that the main body 12 comprises: a tabular display panel 16 being a display screen; a front cover 17 (a front bezel, a mask) which is in front of the display panel 16 and covers a front of the display pane 16; the back cover 15 which is at the back of the display panel 16 and covers the back of the display panel 16; a reflector 18 attached to an anterior surface of the back cover 15; a light source 21 (refer to FIG. 4) attached to a side anterior to the reflector 18 on the anterior surface of the back cover 15; a plurality of optical sheets 22 (refer to FIG. 8) which are attached to an anterior surface of the reflector 18 and are configured to perform various optical functions; and an intermediate member 23 (middle frame) which is at a position anterior to the optical sheets 22. The reflector 18 and the optical sheets 22 are interposed between the back cover 15 and the intermediate member 23.

As shown in FIG. 2, the image display device 11 further comprises: a system substrate 24, a power circuit substrate 25 and a liquid crystal driving substrate 26 which are attached to a posterior surface of the back cover 15; a pair of speakers 27 on the downside of the back cover 15; and a unit cover 28 (second back cover) which is attached to the back cover 15 and covers the components.

The back cover 15 comprises two throttles 31 which longitudinally extend. One of the throttles 31 is on the right side, and the other throttle 31 is on the left side. For example, the throttles 31 have substantially U-shapes in the cross-section, and protrude in the back direction B of the image display device 11. The throttles 31 improve the stiffness of the back cover 15, and prevent the back cover 15 from bending in an anteroposterior direction. As shown in FIG. 2, the system substrate 24 is attached to the right side (the left side from the perspective of the anterior direction) of the right-side throttle 31 (the left-side throttle 31 from the perspective of the anterior direction). The system substrate 24 contains a tuner portion and various chips for image processing, and controls the image display device 11 overall. The power circuit substrate 25 is attached to the left side (the right side from the perspective of the anterior direction) of the left-side throttle 31 (the right-side throttle 31 from the perspective of the anterior direction). Between the two throttles 31, the liquid crystal driving substrate 26 is attached.

The display panel 16 is composed of a liquid crystal cell formed by joining two glass base plates together. The display panel 16 is not limited to the liquid crystal panel. The display panel 16 may be a different type of display panel such as a plasma display panel, an organic EL, a plastic display panel and a sheet display panel. The display panel 16 is attached to the intermediate member 23.

As illustrated in FIG. 1, the front cover 17 is provided in a frame shape by, for example, a synthetic resin material, and exposes the display panel 16 to the outside by an opening in the central portion. The front cover 17, the back cover 15 and the unit cover 28 compose a housing 32 of the image display device 11. Further, the front cover 17, the back cover 15 and the unit cover 28 are integrally attached by attaching means such as screws.

The light source 21 is constructed by a slender base plate 33 (LED base plate) in which a plurality of LEDs are set out. As indicated in FIG. 4, in the present embodiment, the light source 21 is composed of, for example, five base plates 33, and is configured to directly illuminate the display panel 16 from the rear side. Thus, the light source 21 constitutes a so-called direct type of back light. Each of the base plates 33 is held in the back cover 15 by a plurality of hook-like retaining portions 34 in the back cover 15.

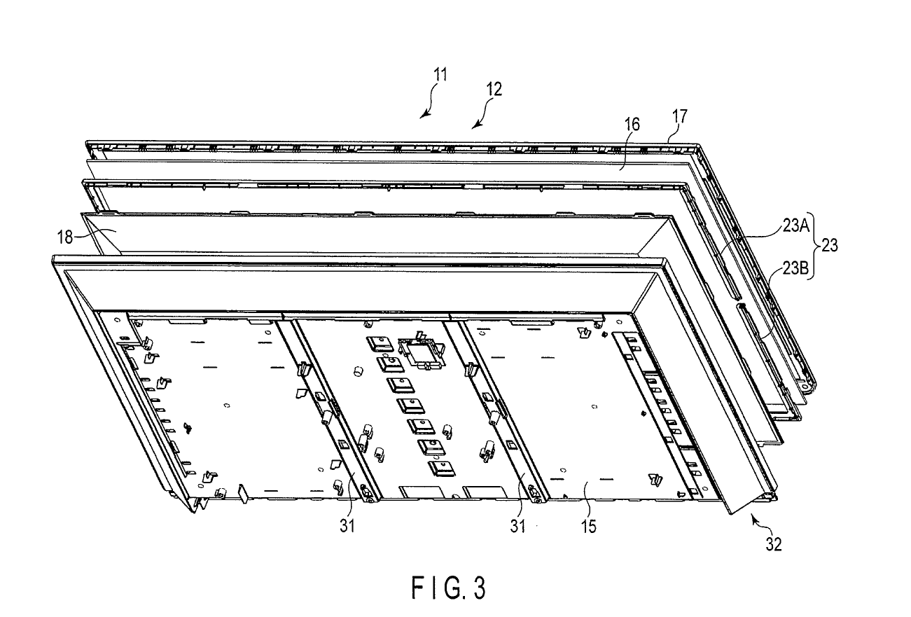

As shown in FIG. 3, the reflector 18 is formed into a saucer shape along an inner surface of the back cover 15.

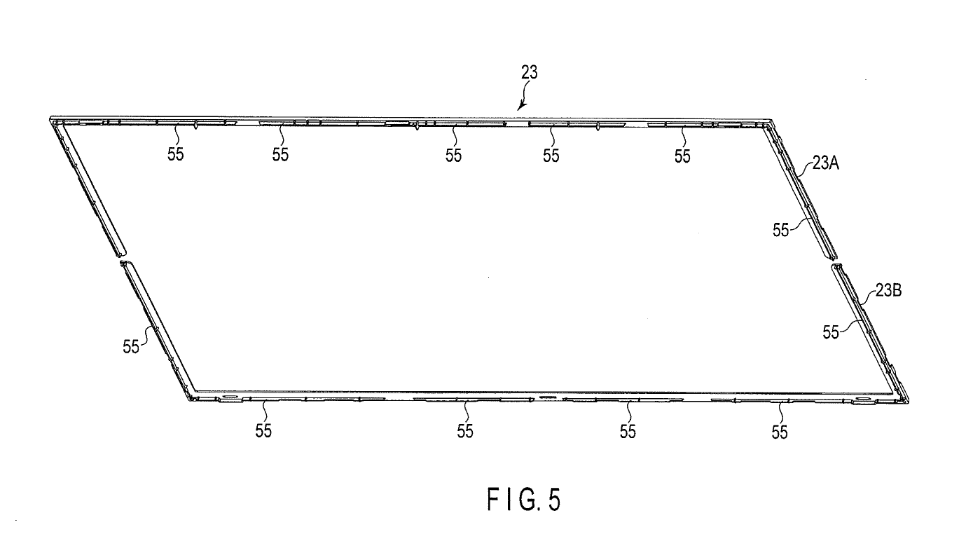

FIG. 5 illustrates that the intermediate member 23 is provided in a substantially frame shape by, for example, a synthetic resin material. The intermediate member 23 is between the display panel 16 and an outer edge region 35. The intermediate member 23 comprises a first member 23A and a second member 23B. The first member 23A has a substantially C-shape, and corresponds to the upper half of the display panel 16. The second member 23B has a substantially C-shape, and corresponds to the lower half of the display panel 16. Each of the first member 23A and the second member 23B comprises fourth ribs 55 protruding to the outer edge region 35. The intermediate member 23 may be formed as one member having a frame shape. However, the intermediate member 23 divided into two members as the present embodiment is good in usability since metallic mold can be small, etc.

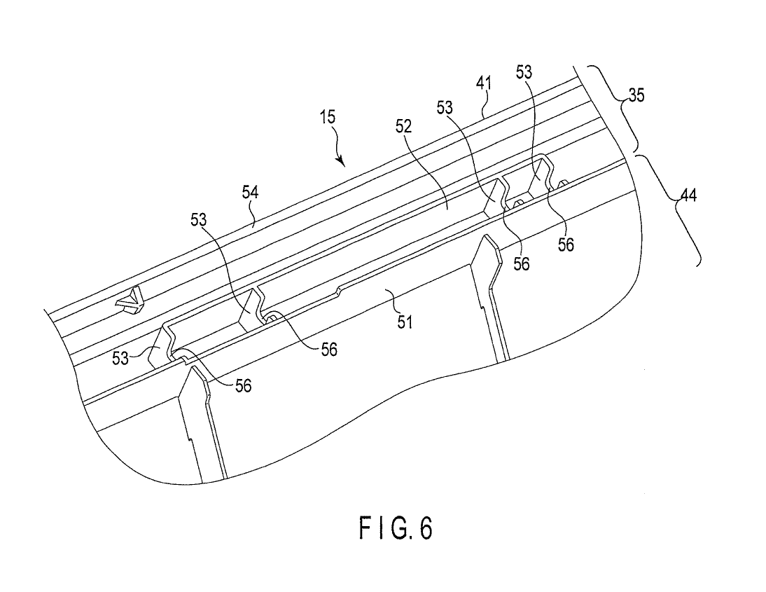

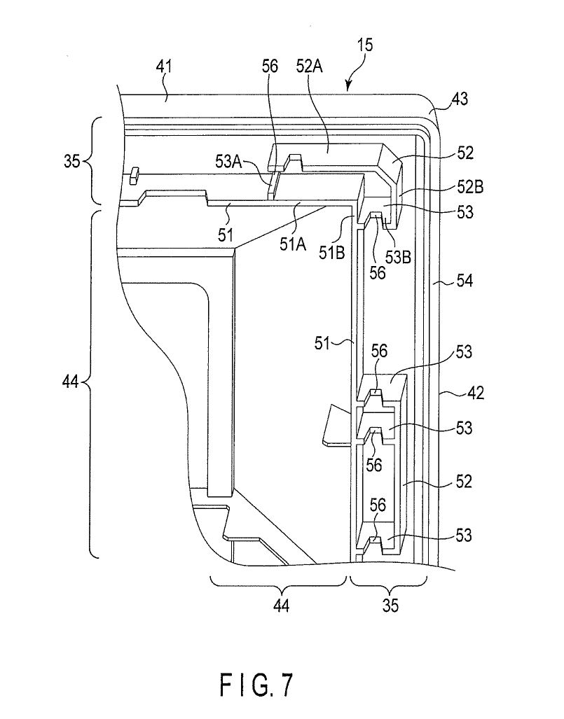

FIG. 4 indicates that the back cover 15 is formed into a square saucer-shape overall. The back cover 15 is integrally molded by, for example, a synthetic resin material. The back cover 15 comprises a first side 41 (long side) along a longitudinal direction of the main body 12, a second side 42 (short side) in a direction intersecting with the first side 41, and a corner 43 at which the first side 41 and the second side 42 intersect with each other. As shown in FIG. 4, FIG. 6 and FIG. 7, the back cover 15 comprises a central region 44 (main region) hollowed in a frustum shape, and the outer edge region 35 along the outer edge of the back cover 15.

As illustrated in FIG. 4, the outer edge region 35 is in a circumference of the central region 44, and surrounds the upper side of the central region 44, and the right and left sides of the central region 44. The outer edge region 35 has a predetermined width, and is provided in a frame shape in the circumference of the central region 44. A plurality of notches 45 are at a position corresponding to the first side 41 on the lower side of the back cover 15 in order to pass various kinds of lines (flexible print wiring boards) extending from the display panel 16 (liquid crystal cell) through.

FIG. 4, FIG. 6 and FIG. 7 show that the back cover 15 comprises a first rib 51 on an inner border of the outer edge region 35, second ribs 52 along the first rib 51 within the outer edge region 35, and third ribs 53 continuous with the first rib 51 and the second ribs 52. The back cover 15 further comprises an outer frame 54 on an outer border of the outer edge region 35. The outer frame 54 constitutes an outer shell of the main body 12 together with the front cover 17.

In other words, the first rib 51 is on a border between the central region 44 and the outer edge region 35. The first rib 51 is continuous along the inner border of the outer edge region 35. The first rib 51 is linear except for a position corresponding to the corners 43 of the back cover 15. FIG. 7 indicates that the first rib 51 has a substantially so-called L-shape at the position corresponding to the corner 43. At the position corresponding to the corner 43, the first rib 51 comprises a first portion 51A corresponding to the first side 41, and a second portion 51B corresponding to the second side 42. The second portion 51B is substantially orthogonal to the first portion 51A. The first rib 51 improves the stiffness of the back cover 15 overall, and is also utilized for the position determination of the reflector 18.

As illustrated in FIG. 4, FIG. 6 and FIG. 7, the second ribs 52 are substantially parallel to the first rib 51. Similarly to the first rib 51, the second ribs 52 are linear except for the position corresponding to the corners 43 of the back cover 15. At the position corresponding to the corner 43, the second rib 52 has a substantially so-called L-shape. At the position corresponding to the corner 43, the second rib 52 comprises a third portion 52A corresponding to the first side 41, and a fourth portion 52B corresponding to the second side 42. The fourth portion 52B is substantially orthogonal to the third portion 52A.

The third ribs 53 extend in a direction substantially orthogonal to the first rib 51 and the second ribs 52. As shown in FIG. 7, at the position corresponding to the corner 43, the third rib 53 comprises a fifth portion 53A continuous with the first portion 51A and the third portion 52A, and a sixth portion 53B continuous with the second portion 51B and the fourth portion 52B. The fifth portion 53A extends in a direction intersecting with the sixth portion 53B.

FIG. 6 and FIG. 7 illustrate that each third rib 53 comprises a groove 56 in which the fourth rib 55 of the intermediate member 23 is fit. The third ribs 53 are configured to determine the position of the intermediate member 23 via the grooves 56.

The first rib 51 forms a substantially circular shape together with the second ribs 52 and the third ribs 53. However, the shape formed by these ribs differs depending on the allocated position. Specifically, as shown in FIG. 6, the first to third ribs 51 to 53 form a substantially quadrangular shape (box shape) at a position distant from the corners 43. On the other hand, as indicated in FIG. 7, at the position corresponding to the corner 43, the first to third ribs 51 to 53 form a substantially polygonal shape (bag shape) including a portion of a substantially double-L-shape. Thus, the substantially circular shape inclusively indicates the substantially quadrangular shape, the substantially box shape, the substantially polygonal shape and the substantially bag shape.

Here, the substantially circular shape does not require that the first to third ribs 51 to 53 should be fully continuous, but means that the first to third ribs 51 to 53 are substantially continuous. Therefore, a part of the first to third ribs 51 to 53 may include a disconnected portion for certain reasons related to mounting, etc.

According to the first embodiment, the electronic apparatus comprises the display panel 16, the back cover 15 which covers the rear side of the display panel 16, the outer edge region 35 along the outer edge of the back cover 15, the first rib 51 on the inner border of the outer edge region 35, the second ribs 52 along the first rib 51 within the outer edge region 35, and the third ribs 53 continuous with the first rib 51 and the second ribs 52.

According to this structure, the stiffness in the outer edge region 35 of the back cover 15 can be improved by the first rib 51, the second ribs 52 and the third ribs 53. Thus, even when a load is applied to the back cover 15 in a torsion direction, it is possible to provide the back cover 15 which can resist the load, and provide the electronic apparatus with high rigidity.

The first rib 51 forms a substantially circular shape together with the second ribs 52 and the third ribs 53. According to this structure, it is possible to efficiently improve section modulus by the ring formed by the first to third ribs 51 to 53 of the outer edge region 35, suppressing the weight increase of the outer edge region 35. Thus, it is possible to provide the electronic apparatus which is strong in the bending load with respect to the substantially ring (i.e., the load in the torsion direction with respect to the back cover).

The electronic apparatus further comprises the outer frame 54 on the outer border of the outer edge region 35. According to this structure, the strength of the outer edge region 35 of the electronic apparatus can be further improved by the combinations of the first to third ribs 51 to 53 with the outer frame 54. Thus, it is possible to provide the electronic apparatus which is strong in the load in the torsion direction with respect to the back cover 15.

In this case, the first rib 51 forms a substantially L-shape at the position corresponding to the corner 43 of the back cover 15, and the second rib 52 forms a substantially L-shape at the position corresponding to the corner 43 of the back cover 15. According to this structure, it is possible to provide the back cover 15 comprising the corner 43 at which a substantially double-L-shape is formed by the substantially L-shape of the first rib 51 and the substantially L-shape of the second rib 52. Thus, the cross modulus is improved at the corner 43, and it is possible to provide the electronic apparatus which is strong in the load in the torsion direction at the corner 43.

The electronic apparatus comprises the frame-like intermediate member 23 between the display panel 16 and the outer edge region 35. The intermediate member 23 comprises the fourth ribs 55 protruding toward the outer edge region 35. The third ribs 53 comprise the grooves 56 in which the fourth ribs 55 are fit. According to this structure, the position of the intermediate member 23 can be determined by using the grooves 56 of the third ribs 53. Thus, it is possible to improve the strength of the back cover 15 and to determine the position of the intermediate member 23 by the simple structure.

The back cover 15 comprises the corner 43 at which the first side 41 and the second side 42 intersect with each other. The first rib 51 comprises the first portion 51A which corresponds to the first side 41, and the second portion 51B which corresponds to the second side 42 and is substantially orthogonal to the first portion 51A. The second rib 52 comprises the third portion 52A which corresponds to the first side 41, and the fourth portion 52B which corresponds to the second side 42 and is substantially orthogonal to the third portion 52A. The third rib 53 comprises the fifth portion 53A continuous with the first portion 51A and the third portion 52A, and the sixth portion 53B continuous with the second portion 51B and the fourth portion 52B.

According to this structure, a substantially so-called polygonal ring-shape can be formed by the first portion 51A and the second portion 51B which are in the first rib 51, the third portion 52A and the fourth portion 52B which are in the second rib 52, and the fifth portion 53A and the sixth portion 53B which are in the third rib 53. Thus, the section modulus can be further improved at the position of the corner 43, and it is possible to provide the electronic apparatus which is strong in the load in the torsion direction at the corner 43.

The back cover 15 is integrally formed by a resin material together with the first rib 51, the second ribs 52 and the third ribs 53. According to this structure, it is possible to decrease the number of components and reduce production costs and assembling man-hour, maintaining the rigidity of the back cover 15 and decreasing the weight of the back cover 15.

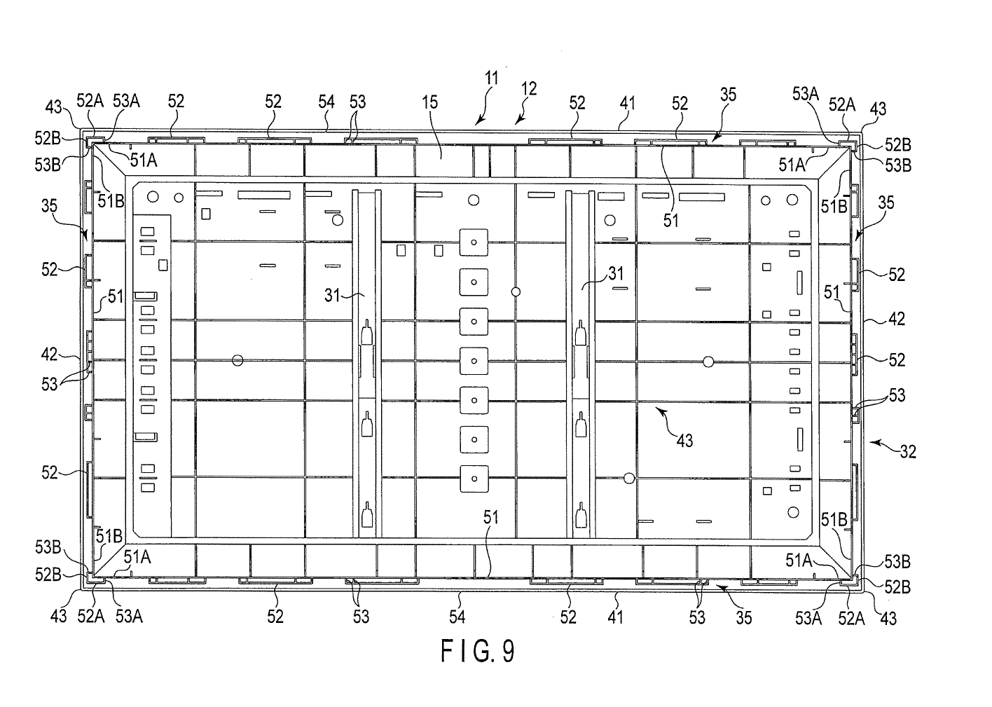

Next, a second embodiment of an electronic apparatus is explained by reference to FIG. 9. An image display device 11 which is an example of the electronic apparatus of the second embodiment is different from the first embodiment in respect that an outer edge region 35 is in a whole circumference of a central region 44. However, in the other portions, the image display device 11 of the second embodiment is common to the first embodiment. Therefore, the portions which are different from the first embodiment are mainly explained. With respect to the portions in common, graphical representation or explanations are omitted.

A back cover 15 is formed into a square saucer-shape as a whole. The back cover 15 comprises a first side 41 (long side) along a longitudinal direction of a main body 12, and a second side 42 (short side) in a direction intersecting with the first side 41. The back cover 15 comprises the central region 44 (main region) hollowed in a frustum shape, and the outer edge region 35 along an outer edge of the back cover 15. The outer edge region 35 is in a circumference of the central region 44, and surrounds the upper and lower sides of the central region 44, and the right and left sides of the central region 44. The outer edge region 35 has a predetermined width, and is provided in a frame shape in the circumference of the central region 44.

The back cover 15 comprises a first rib 51 on an inner border of the outer edge region 35, second ribs 52 along the first rib 51 within the outer edge region 35, and third ribs 53 continuous with the first rib 51 and the second ribs 52. The back cover 15 further comprises an outer frame 54 on an outer border of the outer edge region 35.

The above explanation can be rephrased as follows. The first rib 51 is on a border between the central region 44 and the other edge region 35. The first rib 51 is continuous along the inner border of the outer edge region 35. The first rib 51 is linear excluding a position corresponding to corners 43 of the back cover 15. At the position corresponding to the corner 43, the first rib 51 is shaped in a substantially so-called L-shape. At the position corresponding to the corner 43, the first rib 51 comprises a first portion 51A corresponding to the first side 41, and a second portion 51B corresponding to the second side 42. The second portion 51B is substantially orthogonal to the first portion 51A.

The second ribs 52 are substantially in parallel with the first rib 51. Similarly to the first rib 51, the second ribs 52 are linear except for the position corresponding to the corners 43 of the back cover 15. At the position corresponding to the corner 43, the second rib 52 is formed into a substantially so-called L-shape. At the position corresponding to the corner 43, the second rib 52 comprises a third portion 52A corresponding to the first side 41, and a fourth portion 52B corresponding to the second side 42. The fourth portion 52B is substantially orthogonal to the third portion 52A.

In the present embodiment, a structure in which the substantially L-shape of the first rib 51 and the substantially L-shape of the second rib 52 are doubly arranged is provided near each of the four corners 43.

The third ribs 53 extend in a direction substantially orthogonal to the first rib 51 and the second ribs 52. At the position corresponding to the corner 43, the third rib 53 comprises a fifth portion 53A continuous with the first portion 51A and the third portion 52A, and a sixth portion 53B continuous with the second portion 51B and the fourth portion 52B. The fifth portion 53A extends in a direction orthogonal to the sixth portion 53B.

Each third rib 53 comprises a groove 56 in which a fourth rib 55 of an intermediate member 23 is fit. The position of the intermediate member 23 can be determined by the third ribs 53 through the grooves 56.

The first rib 51 forms a substantially circular shape together with the second ribs 52 and the third ribs 53. However, the shape formed by these ribs differs depending on the allocated position. Specifically, at a position away from the corner 43, the first to third ribs 51 to 53 form a substantially quadrangular shape (box shape). On the other hand, at the position corresponding to the corner 43, the first to third ribs 51 to 53 form a substantially polygonal shape (bag shape) including a substantially double-L-shaped portion.

According to the second embodiment, in the outer edge region 35 on the lower side, in the similar manner, a substantially circular shape is formed by the first to third ribs 51 to 53, and a substantially polygonal shape is formed by the first to third ribs 51 to 53 at each of the four corners 43. Thus, it is possible to provide the electronic apparatus which is strong in the load in the torsion direction of the back cover 15 in comparison with the electronic apparatus of the first embodiment.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An electronic apparatus comprising:
a display panel;
a back cover which covers a rear side of the display panel;
an outer edge region along an outer edge of the back cover;
a first rib on an inner border of the outer edge region;
a second rib along the first rib within the outer edge region; and
a third rib continuous with the first rib and the second rib.

2. The electronic apparatus of claim 1, wherein the first rib forms a substantially circular shape together with the second rib and the third rib.

3. The electronic apparatus of claim 2, further comprising an outer frame on an outer border of the outer edge region.

4. The electronic apparatus of claim 3, wherein
the first rib forms a substantially L-shape at a position corresponding to a corner of the back cover, and
the second rib forms a substantially L-shape at the position corresponding to the corner of the back cover.

5. The electronic apparatus of claim 4, further comprising a frame-like intermediate member interposed between the display panel and the outer edge region, wherein
the intermediate member comprises a fourth rib which protrudes toward the outer edge region, and
the third rib comprises a groove in which the fourth rib is fit.

6. The electronic apparatus of claim 3, wherein
the back cover comprises a corner at which a first side and a second side intersect with each other,
the first rib comprises a first portion corresponding to the first side, and a second portion corresponding to the second side and substantially orthogonal to the first portion,
the second rib comprises a third portion corresponding to the first side, and a fourth portion corresponding to the second side and substantially orthogonal to the third portion, and
the third rib comprises a fifth portion continuous with the first portion and the third portion, and a sixth portion continuous with the second portion and the fourth portion.

7. The electronic apparatus of claim 5, wherein the back cover is integrally molded by a resin material together with the first rib, the second rib and the third rib.
